(19) United States
(12) Patent Application Publication
(10) Pub. No.: US 2015/0146341 A1
(43) Pub. Date: May 28, 2015

(54) ALD dielectric films with leakage-reducing impurity layers

(71) Applicants: GLOBALFOUNDRIES, Inc.; Intermolecular Inc., San Jose, CA (US)

(72) Inventors: Nobumichi Fuchigami, Sunnyvale, CA (US); David Paul Brunco, Latham, NY (US); Karthik Ramani, Santa Clara, CA (US); Dina Triyoso, Mechanicville, NY (US)

(73) Assignees: GLOBALFOUNDRIES, Inc.; Intermolecular Inc., San Jose, CA (US)

(21) Appl. No.: 14/092,431

(22) Filed: Nov. 27, 2013

(51) Int. Cl. H01G 4/10; C23C 16/455; H01G 4/30

(52) U.S. Cl. CPC H01G 4/10; H01G 4/30; H01G 4/306; C23C 16/45525
USPC 361/301.4; 427/79

(57) ABSTRACT

A thin sub-layer (<15 Å) of an impurity is formed under, over, or inside a thicker layer (˜30-100 Å) of a high-k (k>12) host material. The sub-layer may be formed by atomic layer deposition (ALD). The layer and sub-layer are annealed to form a composite dielectric layer. The host material crystallizes, but the crystalline lattice and grain boundaries are disrupted near the impurity sub-layer, impeding the migration of electrons. The impurity may be a material with a lower dielectric constant than the high-k material, added in such a small relative amount that the composite dielectric is still high-k. Metal-insulator-metal capacitors may be fabricated by forming the composite dielectric layer between two electrodes.

### BACKGROUND

Related fields include atomic layer deposition and metal-insulator-metal capacitors.

Traditional device scaling of logic devices based on silicon (Si) has encountered obstacles. Inherent material properties have placed limitations on further miniaturization, increases in processing speed, and other performance enhancements. For example, as gate conductor width decreases, gate dielectric thickness also needs to decrease to provide sufficient capacitance to control the transistor. Suppression of leakage current is critical to performance of a capacitor dielectric. Silicon oxide layers <2 nm thick are subject to unacceptably high leakage current due to tunneling effects.

Tunneling leakage decreases as a function of physical thickness. Therefore, there has been interest in gate dielectric materials that would exhibit the same capacitance as 1-2 nm thick silicon dioxide (SiO₂) at a physical thickness too large for significant tunneling leakage (e.g., >=5 nm). Metal oxides with high dielectric constants (“high-k materials”) such as hafnium oxide (HfO₂, k˜20) and zirconium oxide (ZrO₂, k˜25) are, among others, being investigated as dielectric candidates to replace silicon oxide in such devices as back-end-of-line (BEOL) decoupling capacitors.

A quantity often measured for high-k dielectrics being substituted for silicon oxide is the effective oxide thickness (EOT=(k_{SiO2}/k)t). In the equations, k=dielectric constant of the actual material, t=physical thickness of the actual material, and k_{SiO2}=dielectric constant of SiO₂˜3.9.

When a layer is thick enough to effectively suppress tunneling, other leakage mechanisms may still remain. For example, HfO₂, ZrO₂, and other high-k materials tend to crystallize after annealing, forming polycrystalline material that contains grain boundaries. The resulting grain boundaries provide paths for electrons to travel, thus increasing the leakage current.

Amorphous materials have no grain boundaries, and thus grain boundaries are eliminated as a leakage path.

Therefore, a need exists for a way to form a layer of high-k material that can be annealed without developing the leakage-current paths from grain boundaries in polycrystalline materials.

### SUMMARY

The following summary presents some concepts in a simplified form as an introduction to the detailed description that follows. It does not necessarily identify key or critical elements and is not intended to reflect a scope of invention.

A very thin layer (<15 Å) of a somewhat lower-k impurity material such as aluminum oxide (Al₂O₃, k˜8-9) is deposited by atomic layer deposition (ALD) under, over, or inside a thicker layer (˜30-100 Å) of a high-k host material such as hafnium oxide or zirconium oxide. When the high-k material crystallizes after annealing, the lattice is disrupted where the high-k material meets the impurity sub-layer(s). Potential paths for leakage current are similarly disrupted, particularly in the direction perpendicular to the impurity sub-layer(s) which is most critical to capacitor performance. Because the impurity sub-layers are so thin, the amount of impurity compared to the host material is too small to unacceptably reduce the dielectric constant of the composite layer.

Different embodiments may be selected to optimize different parameters. For instance, placing the impurity sub-layer inside the host material may produce very low leakage current, while depositing the impurity sub-layer first and depositing the host material layer directly on the impurity sub-layer may produce a very low EOT.

The leakage current can be reduced by sandwiching the Al₂O₃ inside the HfO₂, while the EOT can be reduced by depositing the Al₂O₃ first and depositing the HfO₂ directly on it. A post-metal anneal at 300-450 C for 1-120 min produced improved results when the process parameters were varied.

Some embodiments of a thin-film capacitor include a first conductive layer and a second conductive layer (operable as capacitor plates) with a composite dielectric layer between the conductive layers. The composite dielectric layer includes a host material with one or more impurity sub-layers. Each of the impurity sub-layers may be less than about 15 Å thick, or even <=3 Å thick. Near the impurity sub-layers, the lattice structure of the host material may be disrupted or distorted. The host material may be polycrystalline in the absence of lattice-disrupting impurities. The impurity sub-layer may also include some material that would be polycrystalline if no other materials disrupted its lattice structure.

In some embodiments, the dielectric constant k of the host material is greater than that of the impurity material. The dielectric constant k of the impurity may be less than 10. The dielectric constant k of the host material may be greater than 14. The dielectric constant k of the composite dielectric layer may be greater than 12, and may be greater than 80% of the dielectric constant k of the host material. The composite dielectric layer may be about 30-100 Å thick. The composite dielectric layer may have an EOT less than about 20 Å. The composite dielectric layer may have a leakage current density J_{G} less than 0.1 μA/cm² at 1.2V.

In some embodiments, the host material may include a metal oxide (e.g., HfO₂ or ZrO₂). In some embodiments, the impurity may include a metal oxide (e.g., Al₂O₃). The first or second conductive layer may include a metal nitride (e.g., TiN).

A thin-film capacitor may be made by forming a first conductive layer on a substrate, forming a host material layer above the first conductive layer, forming an impurity sub-layer less than about 15 Å thick in direct contact with the host material, forming a second conductive layer, and annealing the substrate. Annealing combines the host material and the impurity into a composite dielectric layer. The annealing temperature may be between about 300 and about 45° C., and its duration may be between about 1 and about 120 minutes. After annealing, the host material forms a polycrystalline lattice, which is disrupted in the vicinity of the impurity. The dielectric constant of the composite dielectric layer may be greater than about 12.

In some embodiments, the impurity sub-layer is formed by ALD. In some embodiments, the host material, or either or both of the conductive layers, are also formed by ALD. The impurity sub-layer may be formed before the host material, so that it is located between the first conductive layer and the host material. The impurity sub-layer may be formed after the host material, so that it is located between the host material and the second conductive layer. The impurity sub-layer may even be formed during the formation of the host material, so that it is located within the host material layer. In some embodiments, there may be more than one impurity sub-layer. The multiple impurity sub-layers may be embedded in the host material, above or below the host material, or a combination. The effective thickness of some impurity sub-layers may be less than 1 Å (averaged over a monolayer that is not fully contiguous).

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate leakage current paths through capacitors with a polycrystalline dielectric and an amorphous dielectric, respectively.

FIGS. 2A-2D conceptually illustrate leakage current paths in capacitors with composite dielectric layers that include impurity sub-layers.

FIGS. 3A-3F conceptually illustrate formation of a composite dielectric layer by ALD.

FIG. 4 is an example flowchart of a method for making a capacitor stack with a composite dielectric including one or more thin impurity sub-layers.

FIG. 5 is a graph of leakage current density vs. EOT from experimental capacitor stacks.

FIG. 6 is a collection of XRD spectra from the experimental capacitor stacks.

### DETAILED DESCRIPTION OF EXAMPLE EMBODIMENTS

As used herein, a material is “crystalline” if it exhibits at least 30% crystallinity as measured by a technique such as x-ray diffraction (XRD). Terms of relative position such as “above”, “below”, “bottom”, “top”, “higher”, “lower”, “upper”, “over”, and “under” are used for convenience; unless clearly indicated otherwise, the scope of invention also includes embodiments with layers in the opposite order to that described. “On” indicates direct contact between described elements. “Above,” “over,” “below,” and “under” allow for intervening elements between the described elements. “About” means “within 10% of.”

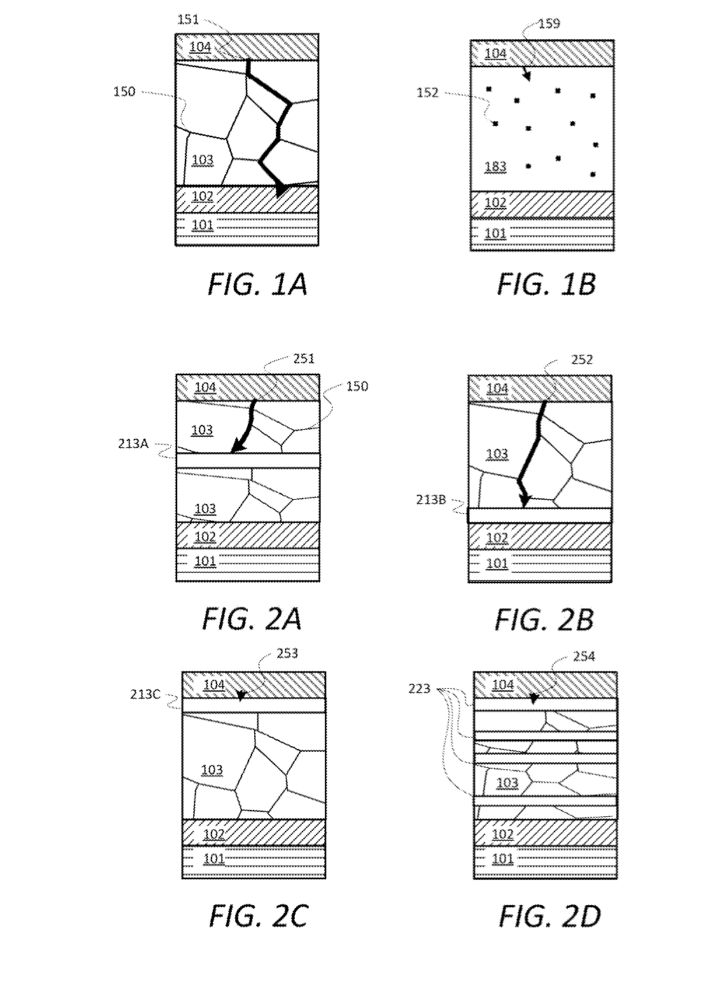

FIGS. 1A and 1B conceptually illustrate leakage current paths through capacitors with a polycrystalline dielectric and an amorphous dielectric, respectively. In FIG. 1A, the capacitor formed on substrate 101 has a polycrystalline dielectric with a network of grain boundaries 103 between a bottom conductive layer 102 and a top conductive layer 104. The conductive layers are operable as electrodes. The network of grain boundaries 150 in polycrystalline dielectric layer 103 allow electrons to travel along connected paths such as 151. Because these paths are available, polycrystalline dielectrics 103 often display unwanted leakage current.

In FIG. 1B, the capacitor formed on substrate 101 has an amorphous dielectric 183 between a bottom conductive layer 102 and a top conductive layer 104. Without an ordered lattice structure and grain boundaries, the amorphous dielectric 183 provides only isolated point defects 152, for example, traps, and thus no continuous conductive path 159 for electrons to travel. Therefore, amorphous dielectrics 183 often have lower leakage current than crystalline or polycrystalline dielectrics.

A lattice structure or grain boundary forming in a layer (for instance, during annealing, which crystallizes many amorphous-as-deposited materials) can be disrupted near an impurity that does not fit into the lattice or continue the grain boundary. An amorphous material may be thought of as a limiting case with a lattice disrupted in so many places that it becomes undetectable. Where the lattice structure and particularly the grain boundaries are disrupted, so are the available paths for leakage current. An impurity sub-layer need not be amorphous to effectively disrupt the lattice or grain boundaries of the host material. It only needs to be structurally different enough to cause a discontinuity in the host material's leakage paths.

An impurity sub-layer may also affect the host material's dielectric constant. That effect depends wholly on the amount of the impurity compared to the host material. The impurity's effect on leakage current, however, depends on both the amount of the impurity and the nature of its dispersal through the host material. Therefore, a small amount of an impurity, strategically dispersed, may decrease leakage current significantly while only slightly affecting the layer's dielectric constant.

In a capacitor, leakage current travels between the two capacitor plates through the most conductive path(s) available. If the conductive paths can be blocked in one or more entire planes of the dielectric parallel to the plates, no highly conductive path between the plates remains. Current may then travel through material on both sides of the blockage plane, but it will not become leakage current if it cannot reach the opposite plate. Therefore, a small amount of impurity may be strategically dispersed to efficiently limit leakage if it is densely in concentrated in one or more thin planes parallel to the capacitor plates.

FIGS. 2A-2D conceptually illustrate leakage current paths in capacitors with composite dielectric layers that include impurity sub-layers. In FIG. 2A, a capacitor formed on substrate 101 has a composite dielectric layer between bottom conductive layer 102 and top conductive layer 104. The composite dielectric layer includes a crystalline or polycrystalline host material 103 and an impurity sub-layer 213A embedded inside the host material 103. The crystalline or polycrystalline morphology of the host material may arise from various different processes in the fabrication of the capacitor; for instance, the host material may be amorphous as-deposited but form crystals during a subsequent heat treatment. Electrons can travel from top conductive layer 104 along the network of grain boundaries 150 of host material 103 until they are diverted by the morphological disruption caused by the presence of impurity sub-layer 213A. In the vicinity of impurity sub-layer 213 A, the unavailability of continuous grain boundaries or an ordered lattice structure causes the composite dielectric layer to behave like an amorphous layer, even though it is mostly made of crystalline or polycrystalline host material 103.

Because the impurity sub-layer 213A extends across the entire area of the capacitor in a plane between bottom conductive layer 102 and top conductive layer 104, leakage current is blocked by the lattice-structure disruption no matter where on the conductive layer it originates. This is a potential advantage over doping methods that scatter dopant throughout the bulk of the host material and may leave some leakage paths between the dopant loci. At the same time, impurity sub-layer 213 A may be very thin compared to host material 103, making the atomic percentage of the impurity in the composite dielectric very small. In some embodiments, more than 90% of the impurity in the composite dielectric may be confined to the impurity sub-layer. Because the impurity is only a small atomic percentage of the composite dielectric, the dielectric constant k of the composite dielectric is dominated by the dielectric constant of the host material 103. Thus, if host material 103 is a high-k material, the composite dielectric can also be high-k even if the impurity is medium-k or low-k.

In FIG. 2B, impurity sub-layer 213B is between bottom conductive layer 102 and host material 103. In FIG. 2C, impurity sub-layer 213C is between host material 103 and top conductive layer 104. The basic mechanism of leakage-current blockage is the same for these configurations. In addition, the conductive-layer-adjacent impurity sub-layers 213B and 213C may be designed to act as buffer layers between the host material and the adjacent conductive layer. For example, some conductive layer materials may diffuse into high-k layers or otherwise react with them, or some high-k oxides may oxidize the conductive layer materials. An impurity that prevents the unwanted reaction between the conductive layer and the high-k layer can be deposited as a conductive layer-adjacent impurity sub-layer and perform that additional function besides blocking the leakage current. Conductive layer-adjacent impurity sub-layers may be combined with embedded impurity sub-layers, or positioned adjacent to both conductive layers, or omitted in favor of multiple embedded impurity sub-layers.

FIG. 2D illustrates multiple impurity sub-layers embedded in or adjacent to the host material. The multiple impurity sub-layers 223 may be separated by thin or thick layers of host material. Although four impurity sub-layers 223 are illustrated, any suitable number may be used. The multiple impurity sub-layers 223 may be adjacent to a conductive layer such as 104 or embedded within in the host material. In some embodiments, the impurity sub-layers may be less than 1 monolayer thick. The impurity sub-layers may form a micro-laminate or nano-laminate with similarly thin intervening layers of the host material, or the intervening layers of host material may be much thicker. As the layers of the laminate become thinner, the laminate effectively becomes an alloy of the host material and the impurity material.

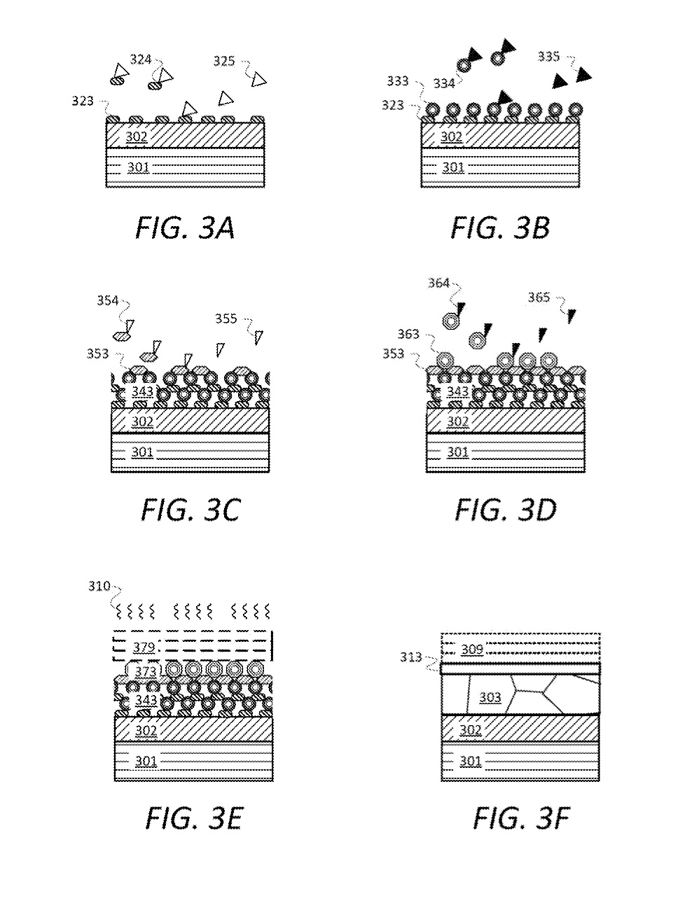

FIGS. 3A-3F conceptually illustrate formation of a composite dielectric layer by ALD. In FIG. 3A, conductive layer 302 has been formed on substrate 301. Substrate 301 may have any number of pre-existing structures and layers underneath conductive layer 302. The upper surface of substrate 302 has been prepared for ALD by any suitable method, such as plasma treatment, wet cleaning or etching processes, or planarization, and positioned in a process chamber.

In the following discussion, the word “substrate” will refer to underlying substrate 301 and any layers formed on it up to the present top surface. For example, in FIG. 3A the substrate is exposed to a first precursor 324 to cause a first deposited material 323 to adsorb onto the present top surface, which in the illustration is the top surface of conductive layer 302. As used herein, “adsorb” may refer to chemisorption, physisorption, electrostatic or magnetic attraction, or any other interaction resulting in part of the precursor adhering to the substrate surface. The self-limiting nature of the ALD process enables the formation of film layers with precision on the atomic or molecular scale. Among those skilled in the art, ALD layer thickness is typically expressed as an average thickness. A contiguous monolayer is one molecule thick. However, a non-contiguous monolayer, where there are empty spaces left between the deposited atoms, can be less than 1 molecule thick on average. In some processes, a ligand 325 may be part of the precursor 324 but not part of the deposited material 323. When the deposited material 323 is adsorbed to the surface, ligand 325 is detached. After depositing one or more atomic monolayers of the first deposited material 323, the chamber may be purged (not shown) to exhaust detached ligands 325 and any remaining unreacted precursor 324.

In this example, first deposited material 323 is a component of a host material. In some embodiments, the host material may be a metal oxide. The metal oxide may be a high-k metal oxide such as hafnium oxide or zirconium oxide. The first deposited material 323 may be the metal component of the metal oxide, such as hafnium or zirconium. Precursor 324 may be a hafnium precursor such as HfCl₄, tetrakis(dimethylamido)hafnium(IV), tetrakis(ethylmethylamido)hafnium(IV), bis(methyl-η5-cyclopentadienyl)dimethylhafnium, hafnium(IV) tert-butoxide, or bis(methyl-η5-cyclopentadienyl)methoxymethylhafnium. Precursor 324 may be a zirconium precursor such as ZrCl₄, bis(methyl-η5-cyclopentadienyl)methoxymethylzirconium, tetrakis(dimethylamido)zirconium(IV), tetrakis(ethylmethylamido)zirconium(IV), or zirconium(IV) tert-butoxide. These options are intended as examples only and do not limit the scope of invention.

In FIG. 3B, the substrate is exposed to a second precursor 334 and the second deposited material 333 adsorbs onto the present top surface of the substrate, which in the illustration is the top surface of the monolayer of the first deposited material 323. Second precursor 334 may include a ligand 335 that detaches from adsorbed second deposited material 333. After depositing one or more atomic monolayers of the second deposited material 333, the chamber may be purged (not shown) to exhaust detached ligands 335 and any remaining unreacted precursor 334.

In this example, second deposited material 333 is a component of a host material. In some embodiments, the host material may be a metal oxide, perhaps a high-k metal oxide such as hafnium oxide or zirconium oxide. The second deposited material 323 may be the oxygen component of the metal oxide and may adsorb by oxidizing the metal. Precursor 324 may be an oxygen precursor such as water (H₂O) or ozone (O₃).

In FIG. 3C, successive exposures of the substrate to the first precursor 324 and the second precursor 334, optionally alternating with purges, have built up a deposited layer 343 of the host material. Only a couple of monolayers are shown for simplicity; in practice, the host material may be much thicker. At this point, the host material does not yet necessarily have a lattice structure. The substrate is exposed to a third precursor 354 so that a third deposited material 353 adsorbs to the top surface, which as illustrated is now the top surface of the host material layer 343. When the atoms or molecules of the third deposited material 353 adsorb to the substrate surface, one or more ligands 365 may be released. After depositing one or more atomic monolayers of the third deposited material 353, the chamber may be purged (not shown) to exhaust detached ligands 355 and any remaining unreacted precursor 354.

In this example, third deposited material 353 is a component of an impurity. In some embodiments, the impurity may be a metal oxide, perhaps a lower-k (compared to the host material) metal oxide such as aluminum oxide or lanthanum oxide. The third deposited material 353 may be the metal component of the metal oxide. Precursor 354 may be an aluminum precursor trimethylaluminum (TMA).

In FIG. 3D, the substrate is exposed to a fourth precursor 364, causing the fourth deposited material 363 to adsorb onto the present top surface of the substrate, which in the illustration is the top surface of the monolayer of the third deposited material 353. Fourth precursor 364 may include a ligand 365 that detaches from adsorbed fourth deposited material 363. After depositing one or more atomic monolayers of the fourth deposited material 363, the chamber may be purged (not shown) to exhaust detached ligands 365 and any remaining unreacted precursor 364.

In this example, fourth deposited material 363 is a component of an impurity. In some embodiments, the impurity may be a lower-k (compared to the host material) metal oxide such as aluminum oxide. The fourth deposited material 363 may be the oxygen component of the lower-k metal oxide and may adsorb by oxidizing the metal. Precursor 364 may be an oxygen precursor such as water (H₂O) or ozone (O₃).

In FIG. 3E, successive exposures of the substrate to the third precursor 354 and the fourth precursor 364, optionally alternating with purges, have built up a deposited sub-layer 373 of the impurity. Only one monolayer is shown for simplicity; in practice, the impurity sub-layer may be multiple monolayers thick. Optionally, other successive layers 379 are formed above the impurity sub-layer 373. The other successive layers 379 may include a top conductive layer, one or more additional host material layers, or both. Now the substrate is subjected to with heating process 310; for example, a rapid thermal anneal (RTA). In some embodiments, the heating process may anneal the substrate at a temperature between about 300-450 C for a duration between 1 and 120 minutes. The host material, the impurity material, or both may be amorphous as-deposited. The host material may at least partially crystallize as a result of annealing. The impurity material may remain amorphous through the anneal, or may crystallize, provided that the post-anneal structure of the impurity material does not continue or connect lattice or grain-boundary leakage paths created in the adjacent host material.

In FIG. 3F, the substrate has cooled after heating process 310. Host material layer 343 forms a crystalline lattice as it cools and becomes crystalline host material 303. Impurity sub-layer 373 also cools to some phase 313; it may cool to an amorphous phase or to a crystalline phase with a different lattice structure than host material 303. Regardless of its phase, impurity sub-layer 313 disrupts the lattice structure, and in particular, grain boundaries, of host material 303 at the interface between the impurity and the host.

In some embodiments, the impurity sub-layer may be formed by ALD, but the host material layer or layers may be formed by some other process, such as a CVD, MOCVD, PVD, or epitaxy. Likewise, conductive layer layers may also either be formed by ALD or by any other suitable method.

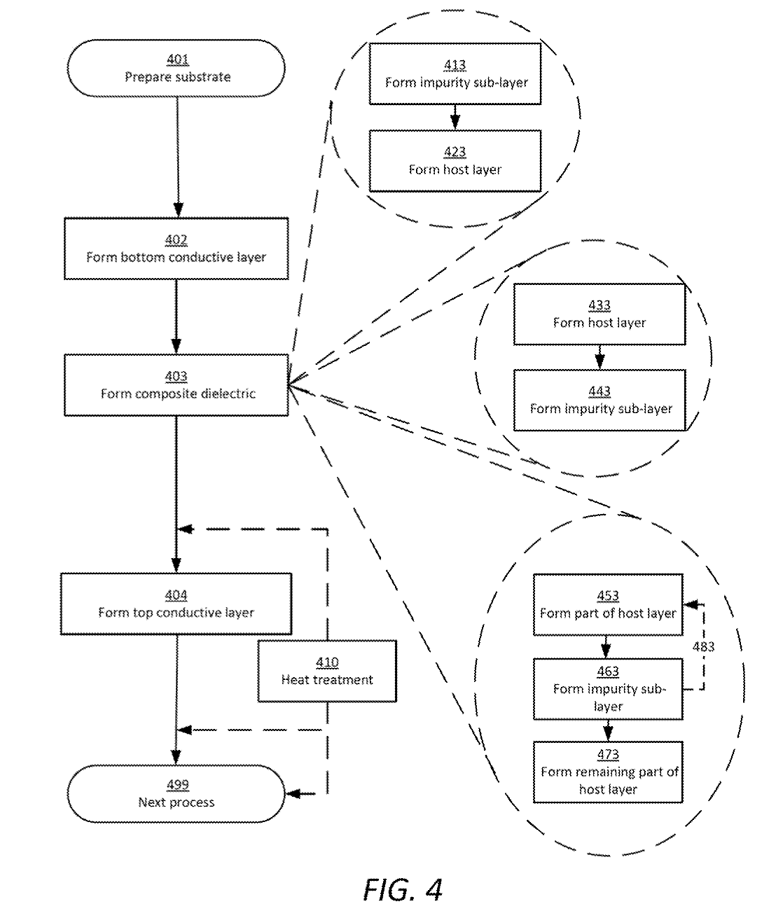

FIG. 4 is an example flowchart of a method for making a capacitor stack with a composite dielectric including one or more thin impurity sub-layers. Initially, the substrate is prepared 401. A bottom conductive layer, operable as an electrode, is formed 402. The composite dielectric is formed 403 above the bottom conductive layer. A top conductive layer, operable as an electrode, is formed 404 above the composite dielectric. Intervening layers may be formed between either of the conductive layers and the composite dielectric.

At some point after the composite dielectric is formed 403, there is a heat treatment 410. Heat treatment 410 may be performed immediately after forming 403 the composite dielectric, or after forming 404 the top conductive layer, or after forming some intermediate layer, or it may be part of a subsequent process 499.

Forming 403 the composite dielectric includes forming at least one layer of host material (“host layer”) and at least one impurity sub-layer. Alternative examples include (a) initially forming 413 the impurity sub-layer and then forming 423 the host layer; (b) initially forming 433 the host layer and then forming 443 the impurity sub-layer; or (c) forming 453 a first part of the host layer, forming 463 the impurity sub-layer, and forming 473 the remaining part of the host layer. If multiple impurity sub-layers are desired, steps 453 and 463 may be iterated 483 multiple times before steps 473. Embodiments with multiple sub-layers may alternatively have the impurity sub-layers on the top, the bottom, or both. Any of the sub-layers or parts of the host layer may be 1 or fewer monolayers thick. Laminates of multiple layers may effectively form an alloy of the host material and the impurity material.

Experimental Results

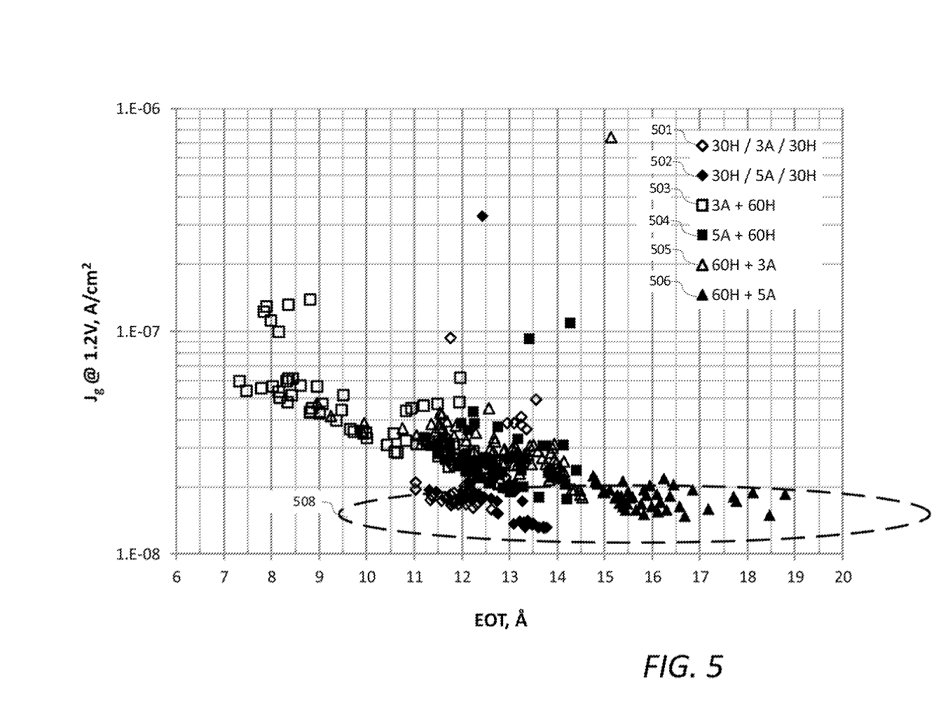

FIG. 5 is a graph of leakage current density vs. EOT from experimental capacitor stacks. In these experiments, the host material was hafnium oxide and the impurity was aluminum oxide. Electrodes were 1000 Å layers of titanium nitride. The total thickness of the host material was 60 Å, 3 Å and 5 Å impurity sub-layers were formed above, below, or in the center of the host material layer. After metallization, the substrates were annealed and subjected to rapid thermal nitridation at 400 C for 1 minute.

In the graph, hollow data point markers are assigned to film stacks with a 3 Å impurity sub-layer, while solid data point markers are assigned to film stacks with the 5 Å impurity sub-layer. Diamond-shaped data point markers are assigned to stacks with an impurity sub-layer embedded in the center of the host layer. Square data point markers are assigned to stacks with the impurity sub-layer between the bottom electrode and the host material. Triangular data point markers are assigned to stacks with the impurity sub-layer between the host material and the top electrode.

Thus, hollow diamond data points 501 correspond to a 3 Å impurity sub-layer embedded between two 30 Å thicknesses of host material (30H+3A+30H). Solid diamond data points 502 correspond to a 5 Å impurity sub-layer embedded between two 30 Å thicknesses of host material (30H+5A+30H). Hollow square data points 503 correspond to a 3 Å impurity sub-layer between a bottom electrode and a 60 Å thickness of host material (3A+60H). Solid square data points 504 correspond to a 5 Å impurity sub-layer between a bottom electrode and a 60 Å thickness of host material (5A+60H). Hollow triangular data points 505 correspond to a 3 Å impurity sub-layer between the host material and the top electrode (60H+3A). Solid triangular data points 506 correspond to a 5 Å impurity sub-layer between the host material and the top electrode (60H+5A).

Encircled region 508 shows the stacks with a leakage current density less than 20 nA/cm². The lowest measured leakage-current density came from (30H+5A+30H) stacks, although the (30H+3A+30H) and the (60H+5A) were also very low. The lowest measured EOT values were seen in the (3A+60H) group, but the leakage current density was higher. The lowest measured EOT values among the stacks with leakage current density less than 20 nA/cm² were between 11 and 12 Å in this data-set.

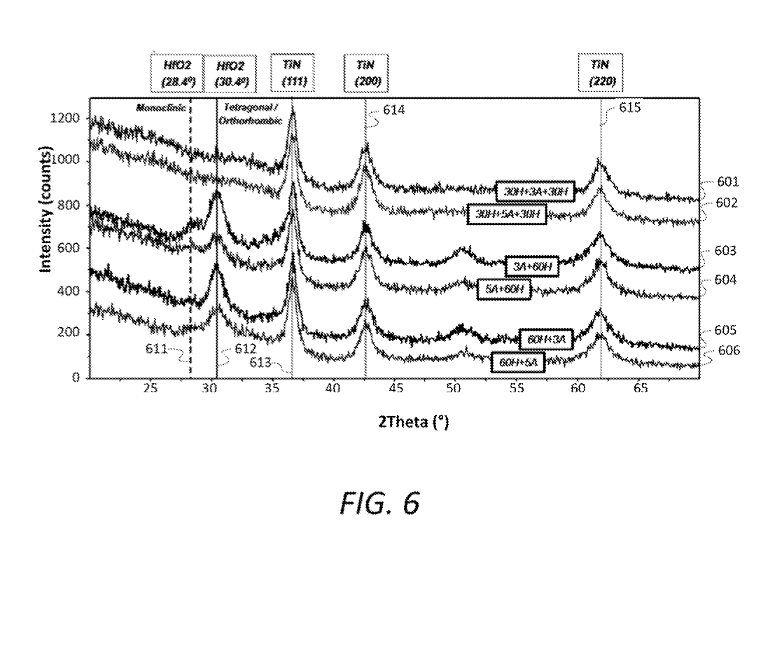

FIG. 6 is a collection of XRD spectra from the experimental capacitor stacks. The three titanium nitride peaks 613 (Miller index 111), 614 (Miller index 200), and 615 (Miller index 220) are informative because the titanium nitride electrodes were intended to be identical for all the stacks. None of the variations of the composite dielectric layer affected the titanium nitride peaks, so it appears that the experiment was well controlled and neither the host material nor the impurity interacted with the electrodes in a way that affected the electrodes' morphology.

Crystalline hafnium oxide has a peak 611 near 2θ=28.4° for monoclinic crystalline formations and a peak 612 near 2θ=30.4° for tetragonal and orthorhombic crystalline formations. Both peaks 611 and 612 are visible on curves 603 (3A+60H) and 604 (5A+60H), but are noticeably attenuated in curve 604 with the thicker impurity sub-layer. Thus the presence of the impurity sub-layer disrupts the host-material lattice and/or grain boundaries sufficiently to attenuate the host-material XRD peaks, compared to a host-material dielectric with no impurity. The monoclinic peak 611 is barely visible in curve 605 (60H+3A) and seems to be completely absent in curve 606 (60H+5A). The tetragonal/orthorhombic peak 612 is still visible in curves 605 and 606, but is weaker in curve 606 corresponding to the thicker impurity sub-layer. Neither of the two host-material peaks is resolvable above the approximately 20-30 counts of peak-to-peak background noise in curves 601 and 602 corresponding to the impurity sub-layer embedded in the center of the host material layer, suggesting that the central embedded impurity sub-layer caused the most disruption in the host material grain boundaries and/or lattice structure.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A thin-film capacitor, comprising:
a first conductive layer;
a second conductive layer; and
a composite dielectric layer between the first conductive layer and the second conductive layer;
wherein the first conductive layer and the second conductive layer are operable as electrodes;
wherein the composite dielectric layer comprises a host material and an impurity sub-layer;
wherein the impurity sub-layer is less than about 15 Å thick and comprises an impurity material; and
wherein a lattice structure or a grain boundary of the host material is disrupted at an interface with the impurity sub-layer.

2. The capacitor of claim 1, wherein a dielectric constant of the host material is greater than a dielectric constant of the impurity material.

3. The capacitor of claim 1, wherein the host material, similarly processed without the impurity sub-layer, would be crystalline or polycrystalline.

4. The capacitor of claim 3, wherein an X-ray diffraction spectrum of a film stack comprising the composite dielectric has attenuated peaks associated with the host material, as compared to a similar film stack with a host-material dielectric having no impurity sub-layer.

5. The capacitor of claim 3, wherein an X-ray diffraction spectrum of a film stack comprising the composite dielectric has no peaks larger than 30 counts associated with the host material.

6. The capacitor of claim 1, wherein a dielectric constant of the composite dielectric layer is greater than about 80% of a dielectric constant of the host material.

7. The capacitor of claim 1, wherein a dielectric constant of the host material is greater than about 12.

8. The capacitor of claim 1, wherein a dielectric constant of the impurity material is less than about 12.

9. The capacitor of claim 1, wherein the composite dielectric layer is between about 30 Å and about 100 Å thick.

10. The capacitor of claim 1, wherein the impurity sub-layer is less than about 10 Å thick.

11. The capacitor of claim 1, wherein the composite dielectric comprises at least one additional impurity sub-layer.

12. The capacitor of claim 11, wherein at least one of the impurity sub-layers is less than about 1 monolayer thick.

13. The capacitor of claim 11, wherein at least part of the composite dielectric is an alloy of the host material and the impurity material.

14. The capacitor of claim 1, wherein the impurity sub-layer is embedded within the host material.

15. The capacitor of claim 1, wherein the impurity sub-layer is between the host material and one of the conductive layers.

16. The capacitor of claim 1, wherein at least one of the impurity sub-layer or the host material comprise a metal oxide.

17. The capacitor of claim 1, wherein the host material comprises hafnium oxide or zirconium oxide and the impurity sub-layer comprises aluminum oxide or lanthanum oxide.

18. The capacitor of claim 1, wherein at least 90% of the impurity material in the capacitor is in the impurity sub-layer.

19. A method of making a composite dielectric layer, comprising:
forming a layer of a host material on a substrate;
forming an impurity sub-layer less than 15 Å thick; and
annealing the substrate at a temperature between about 300 and about 45° C.;
wherein the host material and the impurity sub-layer are in direct contact;
wherein the host material forms a crystalline lattice after the annealing; and
wherein the crystalline lattice is disrupted at an interface with the impurity sub-layer.

20. The method of claim 19, wherein the impurity sub-layer is formed by atomic layer deposition.
